(19) United States
(12) Patent Application Publication
(10) Pub. No.: US 2024/0152114 A1
(43) Pub. Date: May 9, 2024

(54) RADIO FREQUENCY IMPEDANCE MATCHING NETWORK WITH FLEXIBLE TUNING ALGORITHMS

(71) Applicant: Applied Materials, Inc., Santa Clara, CA (US)

(72) Inventors: Yue GUO, Redwood City, CA (US); Kartik RAMASWAMY, San Jose, CA (US); Jie YU, Santa Clara, CA (US); Yang YANG, San Diego, CA (US); Farhad MOGHADAM, Saratoga, CA (US)

(21) Appl. No.: 17/980,378

(22) Filed: Nov. 3, 2022

(51) Int. Cl. G05B 19/414; G05B 19/18

(52) U.S. Cl. CPC G05B 19/4145; G05B 19/182; G05B 2219/45031

(57) ABSTRACT

Embodiments provided herein generally include apparatus and methods, controlled by flexible tuning algorithms, for generating a plasma in a plasma processing chamber. Flexible communications between equipment of the plasma processing system allows sharing of process information and equipment settings for evaluation and refinement of the tuning algorithms used. This enhances the productivity of batch processing of a plurality of semiconductor wafers during the manufacturing process since the tuning algorithms can be modified on the fly during processing thereof. The tuning algorithms may be recorded, reused and/or modified for controlling future plasma processing.

### BACKGROUND

### Field

Embodiments of the present disclosure generally relate to a system that includes radio frequency (RF) power sources and impedance matching networks adapted for generating a plasma in a substrate processing chamber.

### Description of the Related Art

In a plasma processing chamber an RF power source provides RF power to an electrode in the plasma processing chamber for generating plasma therein, via an impedance matching network coupled between the RF power source and the electrode. The RF impedance of a plasma is a complex and highly variable function of many process parameters and conditions. The impedance matching network maximizes power transfer from the RF power source to the plasma in the reactor chamber. This is accomplished when the output impedance of the impedance matching network is equal to the complex conjugate of the input impedance of the plasma in the reactor chamber. The impedance matching network transforms the impedance of the plasma in the reactor chamber to the characteristic operating output impedance of the RF power source, e.g., 50 ohms, for optimal RF power transfer therefrom.

The RF impedance matching network is an electrical module disposed between the RF power source and the plasma reactor to optimize RF power transfer efficiency. To optimize RF power transfer, it is important for the RF impedance matching network to tune at a desired frequency to a desired complex impedance accurately. This is important for providing reliable, efficient and predictable plasma processing results on a semiconductor substrate. In order to ensure operational efficiency and accuracy, the RF impedance matching network depends on the accuracy of associated RF sensors, e.g., RF voltage, RF current and RF power sensors which are used for providing real-time plasma processing conditions, e.g., plasma chamber impedances and RF power being delivered to the plasma chamber during semiconductor manufacturing process operation. However, during the performance of a semiconductor manufacturing process on a substrate the load impedance will change as one or more process variables change during different phases of a plasma processing recipe. Typically, most conventional impedance matching networks utilize a single tuning algorithm that is used to adjust the variable matching components within the matching network to match the load impedance. However, it has been found that most tuning algorithms are not able to appropriately respond to all of the phases of a plasma processing recipe performed on a substrate, which leads to undesirable and inconsistent plasma processing results on the substrate.

Hence, there is a need for a system that solve the problems described above.

### SUMMARY

Embodiments of the disclosure include a system for controlling plasma generation in a plasma processing chamber. The system includes an impedance matching network having a first node adapted for coupling to a radio frequency (RF) power generator, a second node adapted for coupling to an electrode within the plasma processing chamber, and adjustable tuning elements for transforming at least one of a plurality of impedances at the second node to an output impedance of the RF power generator at the first node. The system further includes a tool controller that is in communication with the match controller, and includes instructions that are stored in memory, which when executed by a processor of the tool controller cause a sequence of process recipe steps to be performed in the plasma processing chamber, wherein the sequence of process recipe steps include a first process recipe step, which when executed by the processor, causes at least one process variable to be adjusted to a first setting, and causes a first tuning algorithm of the plurality of tuning algorithms to be executed by the match controller, wherein the execution of the first tuning algorithm causes the at least one of the adjustable tuning elements to be set to a first impedance setting. The sequence of process recipe steps further includes a second process recipe step, which when executed by the processor, causes the at least one process variable to be adjusted to a second setting, and causes a second tuning algorithm of the plurality of tuning algorithms to be executed by the match controller, wherein the execution of the second tuning algorithm causes the at least one of the adjustable tuning elements to be set to a second impedance setting. The selection of the second tuning algorithm is based on a determination that the at least one process variable is adjusted from the first setting to the second setting.

Embodiments of the disclosure include a method for processing a substrate in a plasma processing chamber, by implementing a first process recipe step of a plasma processing recipe, that includes executing, by use of a match controller, a first tuning algorithm, that adjusts at least one adjustable tuning element of an impedance matching network to at least a first impedance setting, and the impedance matching network includes a first node adapted for coupling to a radio frequency (RF) power generator, a second node adapted for coupling to an electrode within the plasma processing chamber, and the at least one adjustable tuning element. Delivering, by use of the impedance matching network, RF power to an electrode disposed within the plasma processing chamber, while the first tuning algorithm is being executed by the match controller, which causes gases disposed within the plasma processing chamber to form or maintain a plasma that has a first load impedance. Implementing a second process recipe step of the plasma processing recipe that includes executing, by use of the match controller, a second tuning algorithm that sets the at least one adjustable tuning element to at least a second impedance setting. Then continuing to deliver, by use of the impedance matching network, RF power to the electrode disposed within the plasma processing chamber. Further adjusting at least one plasma processing variable that causes the first load impedance to change to a second load impedance, while continuing to deliver of RF power while the second tuning algorithm is being executed by the match controller, based on the adjusted at least one plasma processing variable.

Embodiments of the disclosure include an impedance matching network adapted for coupling between an RF power generator and a plasma processing chamber. The impedance matching network includes a first node adapted for coupling to the RF power generator, a second node adapted for coupling to an electrode within the plasma processing chamber, and adjustable tuning elements for transforming at least one of a plurality of impedances at the second node to an output impedance of the RF power generator at the first node. The impedance matching network further includes a match controller coupled to the adjustable tuning elements, wherein the match controller controls setting an impedance transformation with at least one of the adjustable tuning elements by use of at least one of a plurality of tuning algorithms stored in a memory.

### BRIEF DESCRIPTION OF THE DRAWINGS

So that the manner in which the above recited features of the present disclosure can be better understood in detail, a more particular description of the disclosure, briefly summarized herein, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A illustrates a schematic block diagram of a semiconductor wafer plasma processing system, according to one or more embodiments of this disclosure;

FIG. 1B illustrates a schematic diagram of a plasma processing chamber and associated plasma generating equipment that form at least part of the plasma processing system illustrated in FIG. 1A, according to one or more embodiments of this disclosure;

FIG. 2 illustrates a schematic block diagram of an RF power generator, according to one or more embodiments of this disclosure;

FIG. 3 illustrates a schematic block diagram of an RF impedance measurement module, according to one or more embodiments of this disclosure;

FIGS. 4A, 4B and 4C illustrate schematic diagrams of RF tuning circuits, according to one or more embodiments of this disclosure;

FIG. 5 illustrates a schematic block diagram of a match controller, according to one or more embodiments of this disclosure;

FIG. 6 illustrates a graphical plot of DC wafer voltage and reflected RF power versus time for a chamber plasma process recipe performed on a substrate in a plasma processing chamber, according to one or more embodiments of this disclosure;

FIG. 7 illustrates a flow diagram of a tuning recipe that is coordinated with a plasma processing step during the plasma processing of a semiconductor wafer, according to one or more embodiments of this disclosure;

FIG. 8 illustrates a flow diagram of a process that can be executed by the tool controller overseeing the performance of a tuning algorithm, according to one or more embodiments of this disclosure;

FIG. 9 illustrates a flow diagram for the selection of a tuning algorithm based upon plasma chamber conditions, according to one or more embodiments of this disclosure; and

FIG. 10 illustrates a flow diagram that allows the tool controller to decide which of the stored match algorithms should be run during different semiconductor manufacturing process applications in different plasma processing chambers, according to one or more embodiments of this disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and methods for providing an RF impedance matching network with flexible tuning algorithms loadable in real time for use during different portions of a process recipe that may be used during the manufacture of semiconductor devices or other useful products. More specifically, embodiments provided herein generally include apparatus and methods for delivering and using flexible RF impedance matching network tuning algorithms to control the delivery of RF power to a complex load formed within a plasma processing chamber during different phases of a plasma processing recipe used to process a substrate therein. These RF impedance matching network tuning algorithms may be used during different portions of a process recipe executed in the plasma processing chamber as the load impedance changes due to variation in one or more plasma processing parameters. The RF impedance matching network tuning algorithms are configured to take into consideration measured parameter variations, e.g., RF voltage, current and frequency, and make adjustments to the tuning elements of the RF impedance matching network and/or RF power from the RF power generator. In addition, anticipatory adjustments may be provided to the slower response tuning elements of the RF impedance matching network to provide for smoother and more efficient application of the required RF power (voltage) to the complex load formed in the plasma processing chamber. Modifications to other process algorithms based upon historical learning may also benefit and improve the overall operation of the plasma process performed in the plasma chamber.

Tuning algorithms utilized by a matching network may be stored in fast and/or slower module memories depending upon the applications and requirements thereof. The fast module memory may be associated with the match controller but may have a smaller memory capacity, and the slower memory may be associated with the tool controller having larger memory capacity. Since the match controller has very low time latency associated with the match tuning elements it controls, this may be the most effective location for the tuning algorithms due to the often-rapid fluctuations in the load impedance experienced during most plasma processing recipes. However, it is contemplated and within the scope of this disclosure that tuning algorithms stored in the match controller memory may be easily and rapidly changed (replaced) and/or updated with replacement tuning element control algorithms stored in the slower tool controller memory. In some embodiments, the tool controller is configured to make decisions regarding which tuning algorithm is to be implemented by the match controller during different phases of a chamber plasma processing recipe based on stored historical data, settings within the chamber plasma processing recipe that is executed by the tool controller, due to detected changes in one or more plasma processing variables during the performance of the chamber plasma processing recipe, or other useful tuning algorithm selection techniques.

The term “algorithm” as used herein includes a series of instructions, which when executed by a processor, are configured to perform a method or activity described herein. In one example, a tuning algorithm is configured to tune the impedance of the variable impedance generating elements, such as the motorized variable capacitors to a desired position where tuning targets such as minimum reflected power, better power coupling, or others are achieved. The term “recipe” as used herein is a set of rules or instructions that precisely define a sequence of steps and operations for performing one or more functions defined in a plasma chamber. A recipe may select one or more tuning algorithms during one or more of the defined sequence of steps or operations. In one example, based on process conditions, substrate, and chemistry, a preferred algorithm can be selected and defined in a recipe that, which when executed during the manufacturing process, achieves, for example, repeatable and optimized reflected power back to the RF generator. A plurality of predefined and/or “learned” tuning algorithms may be stored in either or both of the fast and slower module memories. A tuning recipe may pick/choose appropriate tuning algorithms stored in either or both memories and transfer the selected tuning algorithms from the slower memory to the faster memory as required. One will note that the tool controller will also include one or more “process recipes” that include a sequence of wafer processing steps that each include process variable settings, which when executed during a process performed in a process chamber produces repeatable substrate (e.g., semiconductor wafer) processing results. Since the storage capacity of the faster memory may be restricted, algorithms no longer required for the process may be replaced with subsequent algorithms required to complete the manufacturing process. Thus, maximizing operational flexibility and minimizing memory storage capacity requirements. The term “fast” or “slow” memory is intended to describe the ability of a controller to transfer and/or implement an algorithm during processing. In one example, a controller that includes a fast memory can be configured to implement an algorithm that is able to make adjustments on the nanosecond (ns) time scale, and a controller that includes a slow memory can be configured to implement an algorithm that is able to make adjustments on the microsecond (μs) time scale.

Embodiments of the present disclosure relate to a plasma processing system comprising independent and autonomous circuit functions having application specific sensor interfaces, data processing, and calculation and control circuit modules. Independent communications between circuit module functions using high speed and secure communication protocols that provide for communications between circuit modules, tool controllers and supervisory systems. Communications may be provided with industrial quality software protocols such as, for example but is not limited to, Ethernet for Control Automation Technology (EtherCAT) or (ECAT). EtherCat communications enables fast and easy circuit and system updating and maintenance in the field, and efficient testing and qualification during the process of manufacturing systems. Sensor and controller circuit testing, qualification and firmware/software updating may be done remotely using File over EtherCAT (FoE), which may reduce maintenance, calibration and logistics costs. Each EtherCat communications interface may have a unique address and be adapted to communicate sensor and control data to the other EtherCat communications interfaces, thereby making available all process information to all circuit functions within a system.

RF matching networks having flexible tuning algorithms may be uploaded to the match controller on the fly, before or during the processing of a semiconductor wafer in a plasma chamber. The tool controller overseeing tuning performance of a tuning recipe can update the tuning algorithms of the tuning recipe on the fly based upon previous process runs or steps. The tuning algorithms may be uploaded to the match controller and/or tool controller using file over EtherCAT (FoE) or other data transfer protocols. The tuning algorithms of the tuning recipe may be uploaded from a user interface such as a personal computer (e.g., laptop PC) using, for example but not limited to, USB, RS-232, RS-422 or other serial communications protocols. Different tuning algorithms may be stored in a match controller memory, tool controller memory and/or user personal computer (PC) memory. Based upon recipe conditions and process requirements, different tuning algorithms may be used for different recipes, process steps, wafer types and the like.

RF Impedance and RF power sensor information from the independent RF impedance and power circuit modules may be shared throughout the plasma processing system(s) for diagnostic purposes and algorithm pre-learning and/or refinement in process speed, quality, and/or efficiency. Circuit modules may provide sensor information that may be reusable for impedance matching unit design extendibility. Sensor circuits may be adapted for use with other impedance matching units and/or operate at other RF frequencies and load impedances. Each sensor circuit module may have a unique communications address and may be accessible with its data available to all other plasma processing system circuit modules, controllers and process data logging in a manufacturing supervisory system.

In some embodiments, sensor data of a plasma process may be used for learning purposes and recorded, then the sensors may be disconnected and the recorded learning process data used in place of the sensor data. The process control algorithm settings, e.g., impedance matching element setting positions and RF power process levels may be stored in a tool controller and subsequently used by the tool controller for a plurality of different tuning recipes. Thus, well established and consistent manufacturing processes may be performed without the necessity of sensor monitoring of the manufacturing processes. This is especially advantageous for a large number of chamber plasma processes occurring during a semiconductor device manufacturing day. The same tuning recipe need not be applied to all of the plasma processing systems at the same time, and may be modified with different process control algorithms depending upon the intended semiconductor manufacturing process required. Different plasma processing tuning recipes may be distributed among the manufacturing plasma chamber systems depending upon the manufacturing requirements for different semiconductor products.

Operational information, e.g., RF sensor values and tuning element positions, may be evaluated during a semiconductor manufacturing process. The operational process information may be recorded (stored in a memory) for subsequent evaluation and possible refinement for performing future manufacturing processes. For example, the plasma chamber condition can change over time, and different or modified RF match tuning algorithms may be implemented with the sum running time to reduce variations. Similarly configured plasma processing chambers may have slight differences which may cause undesirable excess RF reflected power, causing process result variations which can be corrected by adjustments made to a tuning algorithm. Different and adapted tuning algorithms may also be used to reduce chamber-to-chamber variations. Different tuning algorithms may be selected for different process steps when creating a chamber plasma processing recipe. Other examples may be: 1) the use of predetermined impedance match settings (tuning element positions) as a starting match point to compensate for known changes in the load impedance during execution of a chamber plasma processing recipe, 2) anticipating future impedance match settings while taking into consideration the speeds (time) at which the tuning element positions can change to a desired match setting, and 3) making anticipatory tuning element position changes (impedance match points) to compensate for a known change in the load impedance so as to damp and/or reduce the initial high reflected power that may be caused by the load impedance change.

Referring now to the drawings, the details of example embodiments are schematically illustrated. Like elements in the drawings will be represented by like numbers, and similar elements will be represented by like numbers with a different lower-case letter suffix.

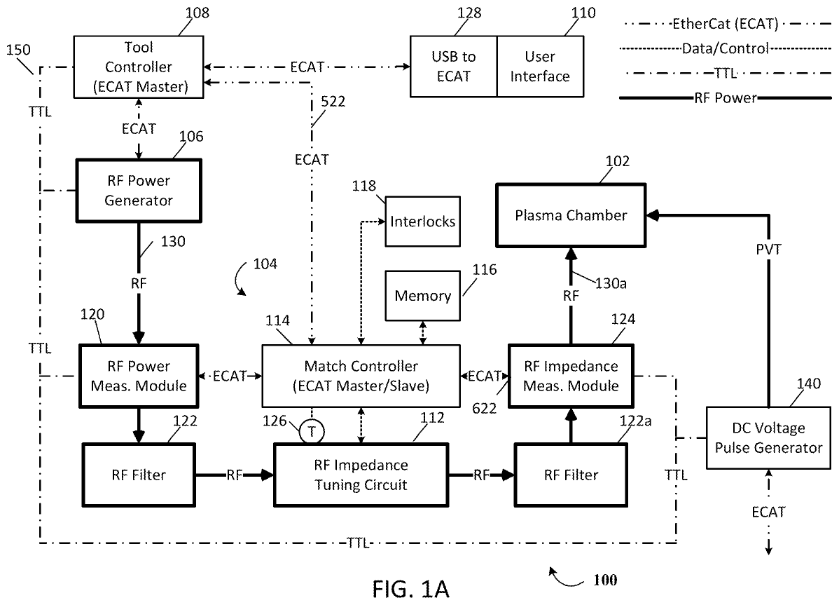

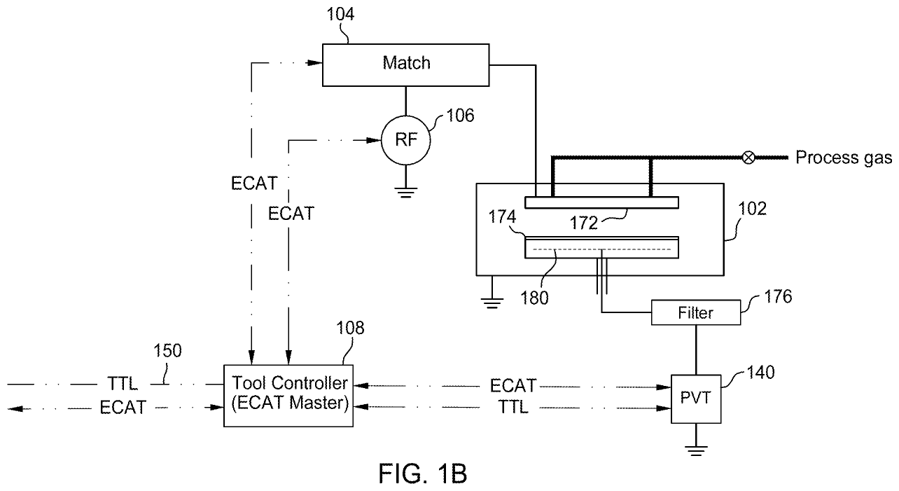

Referring to FIG. 1A, depicted is a schematic block diagram of a semiconductor wafer plasma processing system, according to specific example embodiments of this disclosure. The plasma processing system, generally represented by the numeral 100, may generally comprise a plasma chamber 102 for processing substrates therein, an RF power generator 106, an RF impedance matching network 104, a tool controller 108 and a user interface 110 having a communications interface 128. The plasma processing system 100 may further comprise an RF power measurement circuit module 120, an RF filter 122, an RF impedance matching network 104 comprising an RF tuning circuit 112 and a match controller 114, another RF filter 122a, an RF impedance measurement circuit module 124, and a DC voltage pulse generator 140.

FIG. 1B, illustrates a schematic block diagram of the plasma processing chamber 102 and associated plasma generating equipment, according to one or more embodiments of the disclosure. A plasma processing chamber 102 includes impedance matching unit 104, RF power generator 106, a DC pulse generator 177, an RF electrode 172 and a work piece pedestal 174. The RF electrode 172 is coupled to an impedance matching unit 104 which receive RF power from an RF power generator 106. In one example, the RF electrode 172 could be a showerhead that is used to form a capacitively coupled plasma in the plasma processing chamber 102, or even a multi-turn coil that is used to form an inductively coupled plasma in the plasma processing chamber 102. The impedance matching unit 104, RF power generator 106 and DC pulse generator 177 are monitored and controlled over individual EtherCat communications lines associated therewith. The information from and control of these elements may be processed in a tool controller 108 which communicates to each one over the aforementioned individual EtherCat communications lines. For example, the RF voltage detected with an RF voltage sensor 178 may be utilized by both of the impedance matching unit 104 through the tool controller 108. The output of the DC pulse generator 177 is coupled to an embedded electrode 180 in the work piece pedestal 174. The embedded electrode 180 can be an electrostatic chucking electrode that is disposed within an electrostatic chuck within the work piece pedestal 174. An RF filter 176 is coupled between the DC pulse generator 177 and the embedded electrode 180 and is used to substantially block RF energy from getting into the DC pulse generator 177. The DC pulse generator 177 may be adapted to deliver asymmetric DC pulses to the embedded electrode 180 for control of the plasma sheath formed over the surface of the substrate. In some embodiments, the plasma processing chamber 102 is configured for plasma-assisted etching processes, such as a reactive ion etch (RIE) plasma processing. The plasma processing chamber 102 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (P LAD) processing.

The RF impedance matching network 104, RF power generator 106, RF power measurement circuit module 120, RF impedance measurement circuit module 124, DC voltage pulse generator 140, tool controller 108 and user interface 110 may communicate with each other, to control and monitor the delivery of RF power to the plasma chamber 102 during semiconductor substrate processing, using protocols such as, for example but is not limited to, Ethernet for Control Automation Technology (EtherCAT) or (ECAT). Other industrial communications protocols may also be effectively used and are contemplated herein. For purposes of discussion herein the primary means of communications (protocols) used, for control and monitoring, may be EtherCat. EtherCAT is a high-performance, low-cost, easy to use Industrial Ethernet technology with a flexible topology. More information on EtherCat may be found at the EtherCat Technology website https://www.ethercat.org, incorporated by reference herein for all purposes. EtherCat uses an Ethernet packet form of communications but is much faster and more robust than common Ethernet systems and other similar communication protocols. It is specifically applicable to industrial manufacturing processes requiring a high degree of security and reliability while maintaining high data and control throughput in real time. Since EtherCat is a serial communications protocol with inherent latency delays, a directly coupled signal “TTL” may be utilized for triggering of microsecond sampling and blanking operations during DC pulse generation by the DC voltage pulse generator 140.

The impedance matching network 104 may comprise the RF tuning circuit 112, the match controller 114 for controlling the RF tuning circuit 112, a memory 116 coupled to the match controller 114, safety and operating interlocks 118, an RF power measurement circuit module 120 having an input coupled to an output of the RF power generator 106, an RF filter 122 coupled between the RF power measurement circuit module 120 and an input of the RF tuning circuit 112, another RF filter 122a coupled to the output of the RF tuning circuit 112, an RF impedance measurement circuit module 124 and a temperature sensor 126. The match controller 114 may include a communications interface adapted for a communication protocol such, as for example but not limited to, EtherCat communications. A synchronizing or trigger (TTL) signal 150 may be provided to the circuit modules as indicated and may be adapted to function (programmable) as either a passive (receive) or active (transmit) signal node on a single TTL “party line.” The TTL signal 150 is a hardwired logic circuit that has substantially no communications latency delay and may be used to control RF power blanking, sensor value sampling, DC pulse timing, and other critical timing relationships occurring in the nanosecond or even picosecond ranges. All of the aforementioned circuit modules are accessible between each other for monitoring and control through EtherCat communications, and the TTL signal 150.

A user interface 110, e.g., computer (laptop), may communicate with a tool controller 108 (EtherCat master) using a USB to EtherCat adapter 128 or may be coupled to the tool controller 108 using RS-232, Wi-Fi or other communications protocols, not shown. This communications link may give the user interface 110 access to all sensor information and control of the plasma processing system 100 via, for example but not limited to, EtherCat communications coupled to each subsystem thereof. RF power from the RF power generator 106 may be coupled over high voltage coaxial cable 130, e.g., LMR-600 to the RF power measurement circuit module 120, and RF power from the impedance matching unit 104 may be coupled over coaxial cable 130a to the plasma chamber 102 RF coils (not shown).

Referring to FIG. 1B, the DC voltage pulse generator 140 may comprise a pulse high voltage DC supply that is communication with an EtherCat communications interface. The DC voltage pulse generator 140 is generally configured to provide a voltage waveform that includes asymmetric DC voltage pulses (e.g., non-sinusoidal pulses) to an electrode (e.g., electrode 180) disposed within the plasma processing chamber 102. The DC voltage pulses can include a plurality of voltage pulse characteristics, such as a voltage pulse repetition rate, voltage pulse on-time during a voltage pulse period, and a peak positive or negative voltage applied to the electrode during the on-time of each voltage pulse. In some embodiments, the DC voltage pulses may be generated from about minus (−) 5000 volts to about plus (+) 5000 volts at a pulse repetition rate of from about 100 kHz to about 500 kHz, with pulse on-times provided by the high voltage DC supply of from about five (5) percent to about ninety (90) percent of the pulse period. In one example, the DC voltage pulses includes a minus (−) 5000 volts peak applied voltage that are applied at a pulse repetition rate of about 400 kHz, and pulse on-time that is about 85 percent of the pulse period (e.g., 2.5 μs). During plasma processing it is typical for the voltage waveform, which includes the asymmetric DC voltage pulses, to be provided while the RF power provided from the RF source is used to generate a plasma in the processing region of the plasma processing chamber 102.

DC pulse delivery characteristics for the DC voltage pulse generator circuit module 140 may be stored in a memory of the DC voltage pulse generator 140 and accessed therefrom as required. The delivery and characteristics of the DC voltage pulses (i.e., DC pulse waveforms) provided by DC voltage pulse generator circuit module 140 may also be controlled by signals provided from the tool controller 108 and/or by use of a TTL level signal provided from one or more of the system components. The control of the DC voltage pulse generator may be performed by the tool controller 108 and/or user interface 110 over EtherCat communications lines 822 to the Ethernet communications interface. The synchronizing or trigger (TTL) signal 150 may be provided to the DC voltage pulse generator circuit module 140. The TTL signal 150 may control DC voltage pulse generation profiles according to the DC voltage pulse generator algorithms that may be stored in the memory of the DC voltage pulse generator circuit module 140.

Radio Frequency Impedance and Power Determination

Radio frequency (RF) impedance is determined by the RF voltage V(t), RF current I(t), phase angle θ and frequency of an RF waveform. RF voltage and current sensors measure the RF voltage V(t) and RF current (I(t), and phase angle θ is determined therefrom. Frequency is measured with a frequency detector. Phase angle is the lead or lag times between the RF voltage V(t) and RF current I(t) waveforms at a given harmonic frequency, but fundamental frequency is often considered, and is expressed in degrees θ. RF power P(t) is the product of voltage and current, or P(t)=V(t)*I(t), while the respective RMS (root-mean-square) values after sensor detection are P=V*I*cos θ, where θ is the phase angle between the voltage and current waveforms. Using Ohm's Law Z(t)=V(t)/I(t) or Z may be expressed as Z=R+jX, where R=Z cos θ and jX=Z sin θ. jX=jωL−j/ωC, where ω=2πf, f is in frequency, C is in farads and L is in henrys. R is resistance in ohms and jX is reactance in ohms, where +jX is inductive reactance and −jX is capacitive reactance. Power is frequency independent and impedance is frequency dependent, when analyzing in the frequency domain.

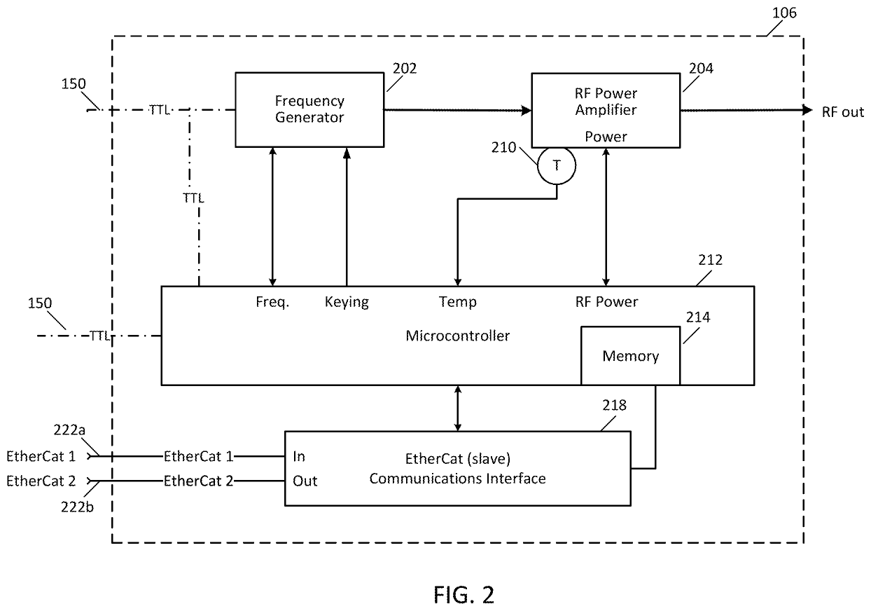

Referring to FIG. 2, depicted is a schematic block diagram of an RF power generator circuit module 106, according to an embodiment of this disclosure. The RF power generator circuit module 106 may comprise a frequency generator 202, an RF power amplifier 204, a temperature sensor 210, a microcontroller 212 having a memory 214, and an EtherCat communications interface 218. The microcontroller 212 is adapted to set the frequency of the frequency generator 202 and the RF power output of the RF power amplifier 204. The RF power generator circuit module 106 may be adapted to provide RF power at frequencies from about 100 kHz to about 200 MHz. RF power output from the RF power generator circuit module 106 may be from about 100 to about 40,000 Watts (W). The RF power may also be pulsed on and off at a pulse rate of from about one Hz to about 100 kHz, with an on/off duty cycle from about one (1) percent to about 99 percent.

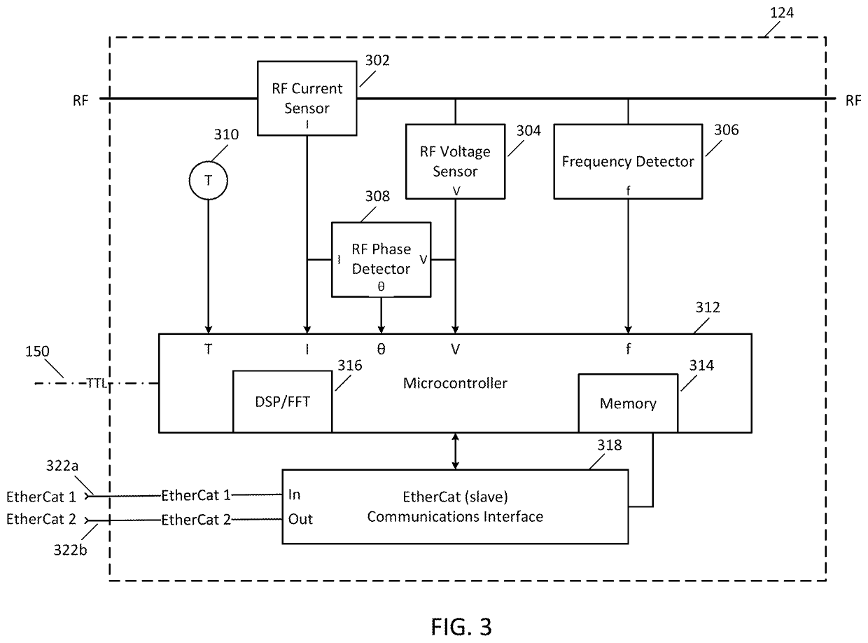

Referring to FIG. 3, depicted is a schematic block diagram of an RF impedance measurement circuit module, according to an embodiment of this disclosure. The RF impedance measurement circuit module, which may include at least one of the RF impedance measurement circuit modules 120 and 124, and may comprise an RF current sensor 302, an RF voltage sensor 304, an RF frequency detector 306, an RF phase detector 308, a temperature sensor 310, a microcontroller 312 having a memory 314 and digital signal processing (DSP)/fast Fourier transform (FFT) 316 capabilities, and an EtherCat communications interface 318. In some embodiments, field programmable gate arrays (FPGAs) or application-specific integrated circuits (ASICs) may be used for faster speed and better performance. The EtherCat communications interface 318 may be adapted for EtherCat-P which may provide DC power for the electronics of the RF impedance measurement circuit module 120, 124. The synchronizing or trigger (TTL) signal 150 may be provided to the microcontroller 312 as an alert to take RF current, RF voltage, RF phase and frequency samples at each trigger pulse from the TTL signal 150. Then the microcontroller 312 may store these samples in the memory 314 for later use, computation and/or communications through the Ethernet communications interface 318. The TTL signal 150 may also be used as a “blanking signal” to prevent sensor readings during a DC pulse from the pulse voltage generator 140.

The RF current sensor 302 senses the RF current I(t) and the RF voltage sensor 304 senses the RF voltage V(t). The RF current I(t) and voltage V(t) are received by analog inputs of the microcontroller 312 and may then be converted into digital representations thereof. The phase angle θ(time difference between I(t) and V(t)) may be determined with the phase detector 308 or may be determined after I(t) and V(t) have been converted into digital representations. Either way the phase angle θ can be converted into a digital format by the microcontroller 312. The frequency detector 306 provides frequency information to the microcontroller 312 in a digital format, e.g., from a time-based digital counter. Once RF current, voltage, phase and frequency are known the impedance may be calculated as well as the RF power going into the load (plasma processing chamber), as described hereinabove, with the DSP/FFT 316 function of the microcontroller 312. The memory 314 may be adapted to store the real time impedances and power calculated and may also be used to store calibration coefficients for the RF current and voltage sensors, and the frequency and phase detectors. Also, sensor, detector, impedance and power information may be presented in digital format from the microcontroller 312 to the EtherCat communications interface 318 for use (information and control) by the plasma processing system 100 and other subsystems thereof.

Impedance Matching Unit Control and Tuning

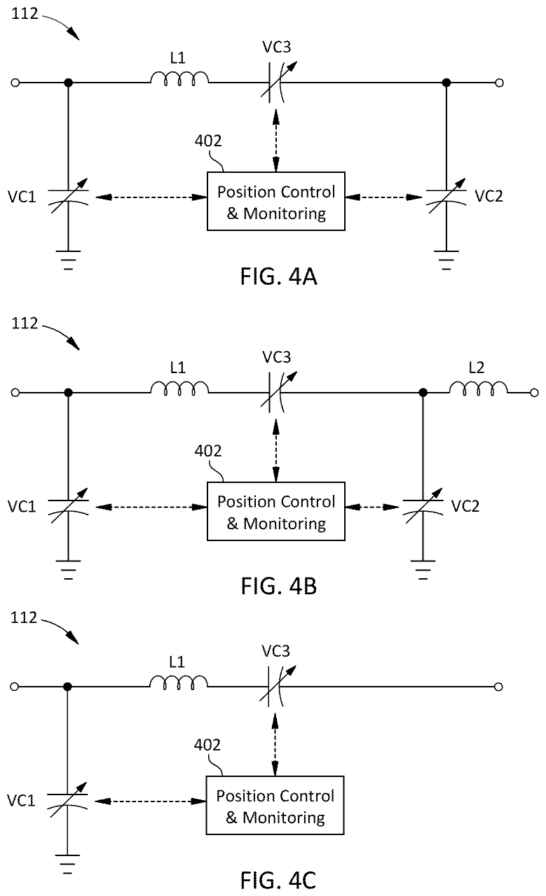

FIGS. 4A, 4B and 4C each include schematic diagrams of RF tuning circuits 112, according to one or more embodiments of the disclosure. FIGS. 4A and 4B show three variable capacitors VC1, VC2 and VC3, and FIG. 4C shows two variable capacitors VC1 and VC3, e.g., motorized vacuum variable capacitors, and are example representations in combination with inductor L1 (and L2) for the RF tuning circuit 112. The variable capacitors VC1, VC2 and VC3 may have a capacitive range, but are not limited to, from about 3 pF to about 5000 pF. L1 is an inductor and may have an inductive range of, but is not limited to, about 0.01 μH to about 1000 μH. VC3 may be used to adjust a target frequency from about 100 kHz to about 250 MHz, and VC1 and VC2 may be used to tune to a target impedance. In some embodiments, especially complex loads for lower frequencies, the RF circuit schematic configuration shown in FIG. 4B may be implemented. An additional inductor L2 may be added for adjusting the RF tuning circuit 112 to a desired value. Inductor L2 may be in a range of, but is not limited to, about 0.01 μH to about 1000 μH. A low pass Pi matching circuit is shown in FIGS. 4A and 4B. In some embodiments, the RF tuning circuit 112 may be an L type circuit as shown in FIG. 4C, using only two motorized vacuum variable capacitors, e.g., VC1 and VC3.

The capacitance and/or inductance values of the variable elements, e.g., VC1, VC2, VC3; may be controlled and monitored by a position control and monitoring circuit 402 for each variable element (one shown). Additional capacitors and/or inductors may also be switched into the matching circuit as required (not shown). A motor position actuator of the position control and monitoring circuit 402 may also include a position sensor that indicates the mechanical position of the adjustable element, e.g., amount of shaft rotation of the variable vacuum capacitor or a synchronized stepper motor position count after minimum and maximum rotation positions have been determined (detection of maximum and minimum clockwise and counter-clockwise shaft rotations). Position values may be correlated in a capacitance (or inductance)—position value table so that capacitance and/or inductance values may be monitored and set to a desired position based upon a required capacitance/inductance value. Tuning element position values may be used for monitoring and presetting tuning element positions according to the teachings of this disclosure.

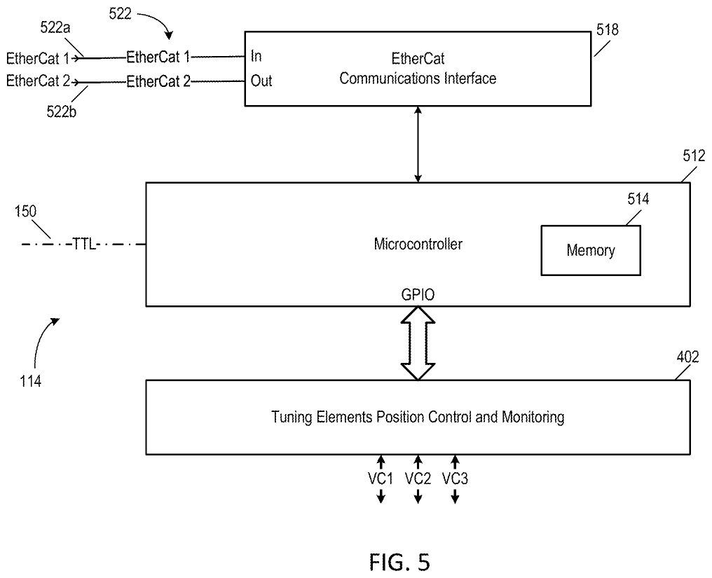

Referring to FIG. 5, depicted is a schematic block diagram of a match controller 114, according to an embodiment of this disclosure. The match controller 114 may monitor and control the variable tuning elements (e.g., variable capacitors VC1, VC2 and VC3) of the RF tuning circuit 112. The match controller 114 may comprise a microcontroller 512, a memory (volatile and/or non-volatile) 514, stepper motor drivers and position sensors 402 (FIGS. 4A-4C), and an EtherCat communications interface 518. The microcontroller 512 can include a processor that is configured to execute the instructions found within the tuning algorithm to adjust and control at least one of the capacitance and inductance values of the variable elements (e.g., VC1, VC2, VC3) within the RF tuning circuit 112. Via EtherCat communications, the microcontroller 612 may receive plasma chamber impedance information from the RF impedance measurement circuit module 124 and/or the RF power measurement circuit module 120. Then from this impedance information control the positions of the variable tuning elements (e.g., variable capacitors VC1, VC2 and VC3) of the RF tuning circuit 112 to complete an impedance match between the RF power generator 106 and plasma chamber 102. The EtherCat communications interface 518 may provide downloaded match tuning algorithms for storing in the memory 514. The TTL signal 150 may initiate a match tuning event or inhibit one depending the match tuning algorithm in operation. Tuning latency issues caused by the slowness of the mechanical movements of the variable tuning elements may be compensated for by, for example but are not limited to, presetting and anticipatory adjustments to minimize adjustment latency times of tuning element control in an impedance matching network during a semiconductor manufacturing process.

### Plasma Processing Example(s)

In an effort to control the processes performed in a plasma processing chamber 102, a chamber plasma processing recipe is typically generated from input provided by a user, such as process engineer. The chamber plasma processing recipe is controlled by a process recipe algorithm that is stored in memory and executed by use of a processor of the tool controller 108. The chamber plasma processing recipe will include a series of processing steps that are each used to define and control one or more substrate processing variables during each processing step, such that when the processing steps are combined together a desired process result is achieved on a substrate. The chamber plasma processing recipe includes a plurality of the processing steps that are generally referred to herein as process recipe sub-steps, or sub-steps. In general, the substrate processing variables will include, but are not limited to, chamber pressure, gas flow rate, gas flow composition, PV waveform bias voltage, PV waveform pulse frequency, PV waveform pulse on-time, RF power level, RF pulse frequency, substrate temperature, or other useful processing parameters. As the various processing steps of the chamber plasma processing recipe are performed, the tool controller 108 will provide or cause commands to be provided to various hardware and electrical components within the plasma processing chamber 102 that are used to execute aspects of the chamber plasma processing recipe and achieve the desired processing results on a substrate. The commands provided from the tool controller 108 can be supplied by use of the various EtherCat communications interfaces and TTL signal lines that enable the communication between the various hardware and electrical components within the plasma processing chamber 102.

As part of the process of controlling the various processing parameters defined in the chamber plasma processing recipe, the tool controller 108 is also configured to cause the match controller 114 to implement tuning algorithms that control the performance of the RF match 104 during processing. As noted above, these tuning algorithms may be used during different portions of a chamber plasma processing recipe executed in the plasma processing chamber as the load impedance changes due to variation in one or more plasma processing parameters. The tuning algorithms are configured to take into consideration measured parameter variations, e.g., RF voltage, current and frequency, and make adjustments to the tuning elements of the RF impedance matching network and/or RF power from the RF power generator. The tuning algorithms can be formed based upon historical learning, user derived settings, or attributes of the current process variables within a process recipe step so that the overall operation of the plasma process performed in the plasma chamber can be improved. In some embodiments, different RF tuning algorithms may be provided based upon RF source, DC voltage pulse source and match synchronization settings when using synchronizing or trigger (TTL) signals. Different RF power algorithms may be provided when using synchronizing or trigger (TTL) signals generated from the RF power generator circuit module 106, from the DC voltage pulse generator circuit module 140 or from an external trigger signal. RF power algorithms for controlling the RF power generator circuit module 106 may be stored in the memory 214 and accessed therefrom as required. These RF power algorithms may be transferred from the tool controller 108 and/or user interface 110 memories over EtherCat communications lines 222 to the Ethernet communications interface 218 and stored in the memory 214 of the microcontroller 212. The synchronizing or trigger (TTL) signal 150 may be provided to the frequency generator 202 and microcontroller 212. The TTL signal 150 triggering may be programmed with the RF power algorithm, as part of a process recipe, which may be stored in the memory 214.

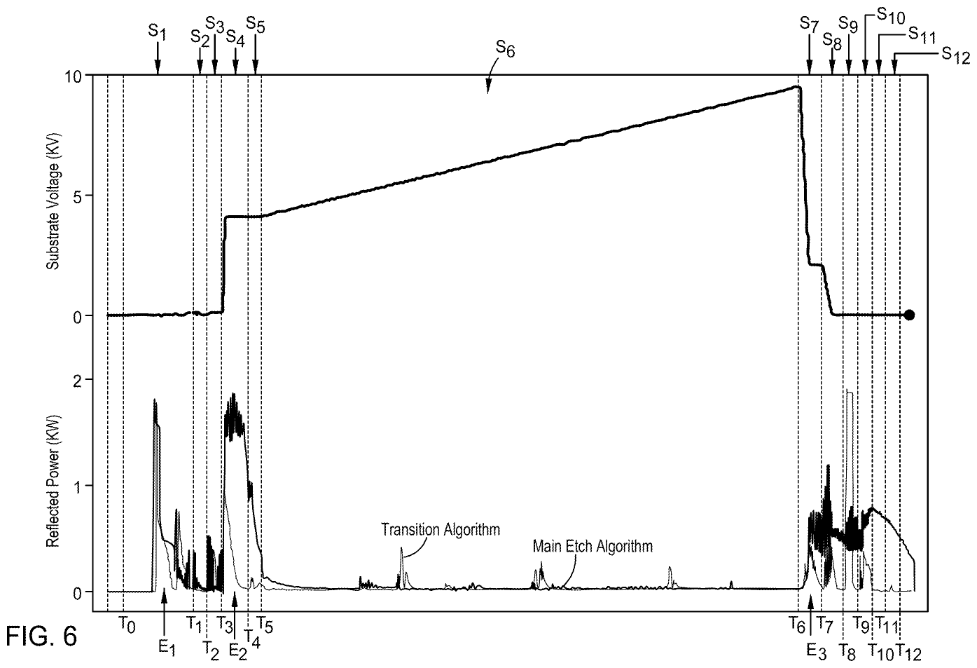

FIG. 6 is a graphical plot of DC wafer voltage and reflected RF power versus time for a chamber plasma process recipe performed on a substrate in a plasma processing chamber 102, according to the teachings of this disclosure. In this example, the chamber plasma processing recipe includes a plurality of sub-steps, such as sub-steps S₁-S₁₂, that each include instructions, which are used by a tool controller 108 to adjust one or more plasma processing parameters during plasma processing to achieve a desired process result on a substrate. In general, the start and duration of each sub-step can vary based on the plasma process that is being performed in the plasma processing chamber 102. As illustrated in FIG. 6, the sub-step starting times include times T₀ to T₁₂, where T₀ is the start of the chamber plasma processing recipe, and the sub-step duration can be found by taking the difference between the starting times. For example, the duration of sub-step S₆ is the difference between time T₆ and T₅. As noted above, the execution of the chamber plasma processing recipe is typically performed by use of a process chamber algorithm running on the tool controller 108. The coded instructions found within the process chamber algorithm are used to cause the tool controller 108 and/or match controller 114 to select and use one or more tuning algorithms during each of the one or more of the sub-steps of the chamber plasma processing recipe. The one or more tuning algorithms may be stored in the tool controller 108 and/or match controller 114 memories and retrieved therefrom for implementation during one or more of the sub-steps. A process recipe performed in a plasma processing chamber 102 may use different tuning algorithms at different phases (e.g., sub-steps) of the process recipe that is executed by the tool controller 108.

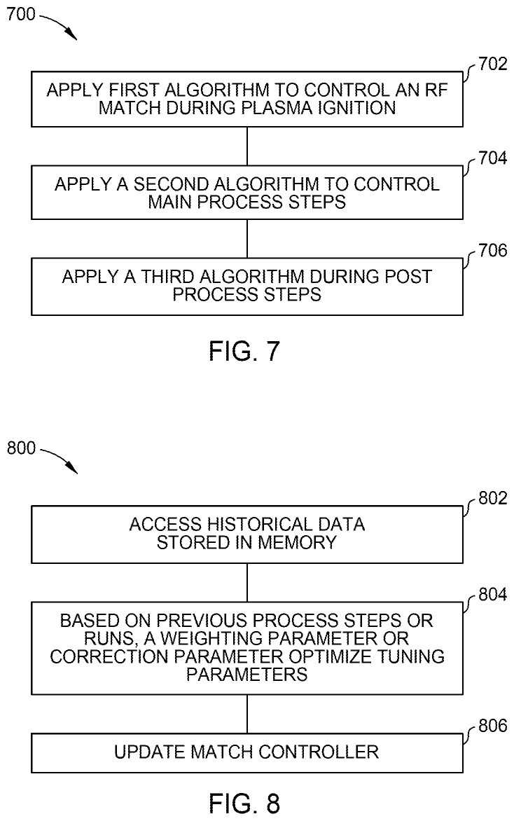

FIG. 7 illustrates a method 700 that includes a plurality of different tuning recipes that are selected based on information stored within one or more of the process recipe sub-steps of a chamber plasma processing recipe, such as the chamber plasma process recipe illustrated in FIG. 6. The series of different tuning recipes are coordinated with the execution of one or more of the plasma processing steps, such as sub-steps S₁-S₁₂, during the plasma processing of a semiconductor wafer. During each of the steps 702-706, a process control algorithm running within the tool controller 108 is used to define which tuning algorithm is to be implemented by the match controller. The implemented tuning algorithm generates control commands that are delivered to the position control and monitoring circuit 402 so that the capacitance and/or inductance values of the variable elements (e.g., VC1, VC2, VC3) within the RF tuning circuit 112 of the match network 104 are adjusted to compensate for the varying impedance of the complex load due to changes in the processing parameters in the plasma processing chamber. The tuning algorithm settings, e.g., impedance matching element setting positions may be stored in a tool controller or match controller and subsequently used at different phases within one or more of the steps 702-706 of plasma processing recipe, such as the one illustrated in FIG. 7.

In step 702, a first tuning algorithm is used for a plasma ignition portion of a process recipe step. For exemplary purposes, in step 702, the chamber plasma processing recipe selects a first tuning algorithm stored in memory to be used by the RF match during the delivery of RF power to the load during the first sub-step S₁. In one example, the first sub-step S₁ of the chamber plasma processing recipe causes a plasma to be ignited within the processing region of the plasma processing chamber. During the sub-step S₁ the tuning algorithm implemented by the match controller 114 adjusts the position of the variable tuning elements, such as the three variable capacitors VC1, VC2 and VC3 illustrated in FIG. 4A, to match to an impedance of the plasma chamber RF load. In one example, the first tuning algorithm is adjusted due to the chamber plasma processing recipe including an initial delivery of RF power to gases disposed in the processing region of the plasma processing chamber 102.

In step 704 of method 700, the chamber plasma processing recipe is used to select a second tuning algorithm, which is stored in memory, and is to be used by the RF match during the delivery of RF power to the load during one or more plasma processing steps, such as the second sub-step S₂. During the sub-step S₂ the tuning algorithm executed by the match controller 114 readjusts the position of the variable tuning elements, such as the three variable capacitors VC1, VC2 and VC3, to match a change in impedance of the load. In one example, the change in the impedance load is at least partially caused by the delivery of a plurality of DC voltage pulses of a voltage waveform provided by the DC voltage pulse generator 140 during at least the second sub-step S₂. In some cases, the second tuning algorithm is utilized for all of the remaining sub-steps (i.e., sub-steps S₂-S₁₂) of the chamber plasma processing recipe. However, in other embodiments, step 704 may be repeated multiple times using a different tuning algorithm for each sub-step to desirably control the delivery of RF power to the load in each of the sub-steps.

In step 706, during a post process step, a third tuning algorithm is utilized to allow a cleaning process recipe to be performed on the plasma processing chamber components when a substrate is not present in the processing chamber 102. During the post process step, the tuning algorithm executed by the match controller 114 readjusts the position of the variable tuning elements, such as the three variable capacitors VC1, VC2 and VC3, to match a change in impedance of the load. In one example, the tuning algorithm is adjusted due to the chamber plasma processing recipe, or an alternate chamber plasma processing recipe, includes an adjustment in the composition of the gases and/or RF power provided to the processing region of the plasma processing chamber 102.

Referring to FIG. 6, during the performance of the sub-steps within a chamber plasma process recipe one or more events, such as events E₁-E₃, may occur as one or more plasma processing parameters are adjusted during a sub-step. During sub-step S₁, during time T₀ and T₁, a high reflected power is experienced during a first event E₁ as a plasma is generated in the plasma processing chamber. The first tuning algorithm is thus used during the first event E₁ to adjust the variable tuning elements to a first setting to reduce the amount of reflected power experienced during this period of time. The tuning algorithm and its chosen variable tuning element settings may have been derived from prior testing or prior processing of substrates using the same chamber plasma process recipe. In some embodiments, the control of the adjustment of the set point of the variable tuning elements is controlled by the tuning algorithm to adjust for real time variations in plasma generated in the plasma processing chamber. In some cases, the speed with which the algorithm makes adjustments to the variable tuning elements or an amount of a damped response that is applied to the adjustments, for example, is set within each tuning algorithm that is applied by the match controller 114 during a sub-step to account for the characteristics of the event experienced during the sub-step. In one example, the speed with which the tuning algorithm reacts to a change in a detected amount of reflected power during the first event E₁ is greater than the speed that the tuning algorithm reacts to a change in a detected amount of reflected power during the third event E₃ due to the magnitude of change or differing rate of change in the amount of reflected power experienced during these sub-steps. In some embodiments, a process of setting the impedance of a variable tuning element (e.g., one or more of the capacitors VC1, VC2 and VC3), which is performed during the execution of a tuning algorithm, includes adjusting a set point of at least one of the variable tuning elements and/or the rate at which the set point is adjusted.

Referring to FIG. 8, a method 800 that can be executed by the tool controller 108 overseeing the performance of a tuning algorithm, according to an embodiment of this disclosure. In the tool controller 108, learning based algorithms may be utilized to oversee and update match tuning performance of the tuning algorithms, and may update the tuning algorithms on the fly based upon the operations and results of previous process recipes or steps. In step 802, the tool controller accesses historical data stored in a memory that was completed in prior process step(s). The historical data can include information relating to reflected power and tuning speeds of variable impedance components of the RF match, which are used as a baseline or as the final tuning parameters that are implemented by the match controller 114. In step 804, a weighting parameter or correction parameter is empirically developed or provided by a user to optimize tuning gain and/or a tuning matrix based upon previous process steps or runs. In step 806, a new tuning algorithm may be generated, stored in memory of the tool controller 108 or match controller 114, and then implemented by the match controller during a process recipe during the next process run or next process step.

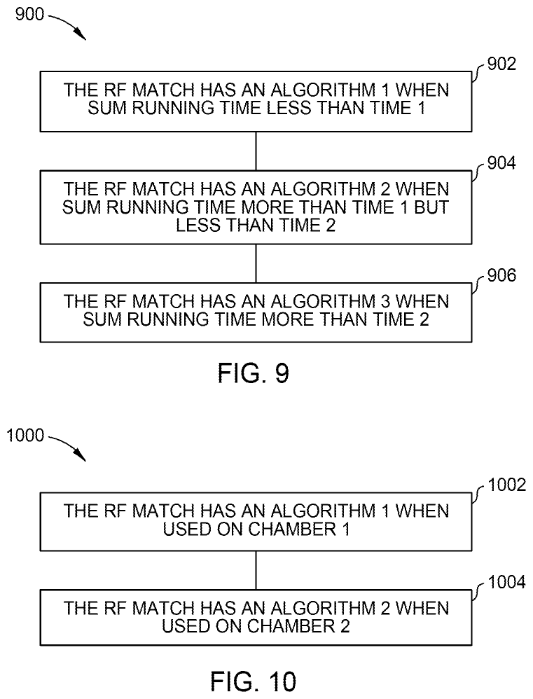

Referring to FIG. 9, includes a method 900 used to select a tuning algorithm based upon the plasma chamber condition, according to specific example embodiments of this disclosure. In step 902, the RF match is controlled by a first algorithm when the sum of the process chamber running time is less than a first time. In step 904, the RF match is controlled by a second algorithm when the sum of the running time is more than the first running time but less than a second time. In step 906, the RF match is controlled by a third algorithm when the sum of the running time is more than the second time. In one embodiment, the first, second and third algorithms are configured to adjust for a drift in one or more of the plasma processing variables over time. In one example, the capacitance of at least one of the three variable capacitors VC1, VC2 and VC3 in the RF tuning circuit 112 is serially increased or decreased by the adjustment of the variable capacitor settings provided by each of the first, second and third algorithms.

FIG. 10 illustrates a method 1000 that allows the tool controller to decide which of the stored match algorithms should be run during different substrate manufacturing process applications in different plasma processing chambers, according to an embodiment of this disclosure. In step 1002, a first RF match algorithm is programmed into and used by a match controller when used with a first plasma chamber. In step 1004, a second RF match algorithm is programmed into and used by the match controller when used with a second plasma chamber. The first and second plasma chambers may be running different process applications that require different tuning algorithms.

The present disclosure has been described in terms of one or more embodiments, and it should be appreciated that many equivalents, alternatives, variations, and modifications, aside from those expressly stated, are possible and within the scope of the disclosure.

What is claimed is:

1. A system for controlling plasma generation in a plasma processing chamber, comprising:
an impedance matching network comprising:
a first node adapted for coupling to a radio frequency (RF) power generator,
a second node adapted for coupling to an electrode within the plasma processing chamber, and
adjustable tuning elements for transforming at least one of a plurality of impedances at the second node to an output impedance of the RF power generator at the first node;
a match controller coupled to the adjustable tuning elements of the impedance matching network, wherein the match controller controls a setting of at least one of the adjustable tuning elements of the impedance matching network by use of at least one of a plurality of tuning algorithms stored in a match controller memory; and
a tool controller that is in communication with the match controller, and includes instructions that are stored in a tool controller memory, which when executed by a processor of the tool controller cause a sequence of process recipe steps to be performed in the plasma processing chamber, wherein the sequence of process recipe steps comprise:
a first process recipe step, which when executed by the processor, causes at least one process variable to be adjusted to a first setting, and causes a first tuning algorithm of the plurality of tuning algorithms to be executed by the match controller, wherein the execution of the first tuning algorithm causes the at least one of the adjustable tuning elements to be set to a first impedance setting; and
a second process recipe step, which when executed by the processor, causes the at least one process variable to be adjusted to a second setting, and causes a second tuning algorithm of the plurality of tuning algorithms to be executed by the match controller, wherein the execution of the second tuning algorithm causes the at least one of the adjustable tuning elements to be set to a second impedance setting.

2. The system of claim 1, wherein the selection of the second tuning algorithm is based on a determination that the at least one process variable is adjusted from the first setting to the second setting.

3. The system of claim 1, wherein the plurality of tuning algorithms are stored in the tool controller memory and one of the plurality of tuning algorithms is stored in the match controller memory.

4. The system of claim 3, wherein at least one of the plurality of tuning algorithms, stored in the tool controller memory, is transferred to the match controller memory while at least one of the process recipe steps is performed.

5. The system of claim 3, wherein at least one of the plurality of tuning algorithms, stored in the match controller memory, is updated with an altered tuning algorithm while at least one of the process recipe steps is performed.

6. The system of claim 5, wherein the altered tuning algorithm is transferred from the tool controller memory to the match controller memory.

7. The system of claim 1, wherein the match controller memory is faster than the tool controller memory.

8. The system of claim 1, wherein the at least one process variable includes a change in a characteristic of a DC voltage pulse applied to an electrode within the plasma processing chamber by a DC voltage pulse generator.

9. The system of claim 8, wherein the change in the characteristic of the DC voltage pulse applied to the electrode comprises an initiation of the delivery of the DC voltage pulse.

10. The system of claim 1, wherein the process of setting the first impedance setting performed during the execution of the first tuning algorithm comprises adjusting a set point of at least one of the adjustable tuning elements and a rate at which the set point is adjusted.

11. A method for processing a substrate in a plasma processing chamber, comprising:
implementing a first process recipe step of a plasma processing recipe, wherein implementing the first process recipe step comprises:
executing, by use of a match controller, a first tuning algorithm, wherein executing the first tuning algorithm comprises adjusting at least one adjustable tuning element of an impedance matching network to at least a first impedance setting, and the impedance matching network comprises:
a first node adapted for coupling to a radio frequency (RF) power generator,
a second node adapted for coupling to an electrode within the plasma processing chamber, and
the at least one adjustable tuning element; and
delivering, by use of the impedance matching network, RF power to an electrode disposed within the plasma processing chamber, wherein the delivery of RF power is provided while the first tuning algorithm is being executed by the match controller, and causes gases disposed within the plasma processing chamber to form or maintain a plasma that has a first load impedance; and
implementing a second process recipe step of the plasma processing recipe, wherein implementing the second process recipe steps comprise:
executing, by use of the match controller, a second tuning algorithm, wherein executing the second tuning algorithm comprises setting the at least one adjustable tuning element to at least a second impedance setting;
continuing to deliver, by use of the impedance matching network, RF power to the electrode disposed within the plasma processing chamber; and
adjusting at least one plasma processing variable that causes the first load impedance to change to a second load impedance, wherein the continued delivery of RF power is provided while the second tuning algorithm is being executed by the match controller, and the second tuning algorithm is executed based on the adjusted at least one plasma processing variable.

12. The method of claim 11, wherein the delivery of RF power provided while the first tuning algorithm is being executed causes the gases disposed within the plasma processing chamber to form the plasma.

13. The method of claim 12, wherein executing the second tuning algorithm comprises replacing the first tuning algorithm with the second tuning algorithm in a match controller memory.

14. The method of claim 13, further comprising uploading, during post process steps, a third tuning algorithm for controlling the at least one of the adjustable tuning elements of the impedance matching network for running cleaning recipe process steps.

15. The method of claim 13, wherein replacing the first tuning algorithm with the second tuning algorithm in the match controller memory comprises accessing historical match tuning process data of a tuning algorithm stored in a tool controller memory.

16. The method of claim 15, wherein the historical tuning algorithm process data comprises RF reflected power and adjustable tuning element adjustment speeds.

17. The method of claim 16, further comprising optimizing tuning element adjustment speeds with a weighting parameter stored in the tool controller memory and based upon the historical process data.

18. The method of claim 16, wherein the second tuning algorithm is formed by generating a new tuning algorithm based upon the historical tuning algorithm process data and storing the new tuning algorithm in the match controller memory for use in a next process run or step.

19. An impedance matching network adapted for coupling between an RF power generator and a plasma processing chamber, comprising:
a first node adapted for coupling to the RF power generator;
a second node adapted for coupling to an electrode within the plasma processing chamber, and
adjustable tuning elements for transforming at least one of a plurality of impedances at the second node to an output impedance of the RF power generator at the first node; and
a match controller coupled to the adjustable tuning elements, wherein the match controller controls setting an impedance transformation with at least one of the adjustable tuning elements by use of at least one of a plurality of tuning algorithms stored in a match controller memory.

20. The impedance matching network of claim 19, further comprising:
a tool controller having a memory for storing the plurality of tuning algorithms; and
a communications device between the tool controller and the match controller for transferring tuning algorithms between the tool controller and match controller memories.
